(19) United States
(12) Patent Application Publication
(10) Pub. No.: US 2012/0261639 A1
(43) Pub. Date: Oct. 18, 2012

(54) STRUCTURES FOR RADIATION DETECTION AND ENERGY CONVERSION USING QUANTUM DOTS

(75) Inventors: Irving N. WEINBERG, Bethesda, MD (US); Pavel STEPANOV, North Potomac, MD (US); Mario G. URDANETA, Berwyn Heights, MD (US)

(73) Assignee: WEINBERG MEDICAL PHYSICS LLC, Bethesda, MD (US)

(21) Appl. No.: 13/179,670

(22) Filed: Jul. 11, 2011

Related U.S. Application Data
(63) Continuation-in-part of application No. 12/123,412, filed on May 19, 2008, now Pat. No. 7,977,643.
(60) Provisional application No. 61/010,929, filed on Jan. 14, 2008.

(51) Int. Cl. H01L 31/0352

(52) U.S. Cl. 257/9; 257/E31.033

(57) ABSTRACT

Inorganic semiconducting materials such as silicon are used as a host matrix in which quantum dots reside to provide an energy conversion device that may be used to convert various types of radiation to electricity.

### CROSS-REFERENCE TO RELATED APPLICATION(S)

This is a Continuation-In-Part application of U.S. patent application Ser. No. 12/123,412 under 35 U.S.C. 120, entitled RADIATION DETECTOR ASSEMBLY, RADIATION DETECTOR, AND METHOD FOR RADIATION DETECTION, filed on May 19, 2008, which in turn application relies for priority on U.S. Provisional Patent Application Ser. No. 61/010,929, filed on Jan. 14, 2008 the entirety of both of which being incorporated by reference herein.

### BACKGROUND

This disclosure concerns an apparatus and a method for radiation detection and/or energy conversion. More specifically, this disclosure describes a semiconductor type composite material useable for radiation detection and/or energy conversion and methods of use of that material.

### SUMMARY

As indicated in U.S. patent application Ser. No. 12/123,412, inorganic semiconductors (for example, silicon) can be used as a host matrix in which quantum dots reside. That application described the utility of conversion of radiation to electricity for the purpose of measuring the form and amount of incident radiation. The currently disclosed embodiments include details regarding the utility of such devices for other purposes, including the conversion of optical radiation from the sun (e.g., solar power), infrared radiation from the earth (e.g., geothermal energy), or emissions from a radioactive source (e.g., as might be used to power a satellite).

### BRIEF DESCRIPTION OF THE FIGURES

Aspects and features of the invention are described in connection with various figures, in which:

FIG. 1 is a cross-sectional view of a disclosed embodiment implemented to provide a “nuclear battery,” wherein the device is provided in proximity to a source of radiation.

FIG. 2 is an axial cross-sectional view of another example of a “nuclear battery.”

### DETAILED DESCRIPTION

As disclosed in U.S. patent application Ser. No. 12/123,412, silicon and other inorganic materials can be used as a host matrix in which quantum dots reside. That application described the utility of conversion of radiation to electricity for the purpose of measuring the form and amount of incident radiation. However, there is additional utility and implementations may be provided for performing energy generation by conversion of various types of radiation into electricity.

For example, currently disclosed embodiments may be utilized to provide photovoltaic functionality. Thus, the currently disclosed embodiments may be used to generate electricity by converting solar radiation into direct current electricity. Accordingly, it should be understood that the disclosed embodiments may be implemented in a manner that the device(s) exhibit a photovoltaic effect and may be used to implement (or be included in) solar cells for use in solar panels and/or arrays.

More specifically, the inventors have experimentally observed that, when embodiments of the device are illuminated with visible-light radiation, there is a flow of electrical current through the device if the device contacts are connected (e.g., a short circuit); similarly, there is a voltage difference if the device contacts are isolated from each other (e.g., an open circuit). This observation suggests that the devices can derive electrical power from incoming visible-light radiation, as a photovoltaic device.

Such an implementation may be provided by connecting the device's electrical contacts directly to a load, for example a motor or electrical lamp.

Alternatively, currently disclosed embodiments may be utilized to provide the ability to generate electricity when the disclosed devices are exposed to infrared energy. Such an implementation may have significant utility in the context of harnessing geothermal energy. More specifically, the inventors have experimentally observed that, when embodiments of the device are exposed to infrared light, the device similarly produces an electrical current. As a result, there is an implication that the disclosed embodiments can be utilized to produce electricity from ambient thermal energy, for example, as a geothermal energy conversion device deriving energy from the earth, sources of geothermal energy in the earth or from other such sources or areas of infrared energy.

Alternatively, currently disclosed embodiments may be utilized to provide technology that may be used in what has been conventionally termed a “nuclear battery” or “atomic battery.” Such devices theoretically use the emissions from a radioactive isotope to generate electricity. Thus, such devices include a source of radioactive emissions and one or mechanisms for converting the emitted radiation into electricity. However, it should be understood that the term “battery” is used loosely, because these devices do not actually store electricity; rather, they generate electricity based on interaction with emitted radioactive radiation.

Based on the observation that the disclosed embodiments may be used to convert incident radiation into electricity, the disclosed device embodiments should produce currents from a wide spectrum of sources of electromagnetic radiation. Thus, the disclosed embodiments can be used to produce electricity from emissions derived from a nearby radioactive material. Examples of radioactive sources include Polonium, Cadmium, and Cobalt isotopes. Such “batteries” could be useful in spacecraft, portable devices, or sensors that require electrical power over long periods of time (i.e., time scales in the same order of magnitude as the radioactivity lifetime of the radioactive source) without interruption.

In at least one disclosed embodiment, an electrode may be deposited upon one side of a host matrix, the host matrix material may be made porous, quantum dots may be deposited in the pores, and an electrode material may be deposited upon the quantum dot layer.

The host matrix material can be made porous through a process known as anodic etching, in which an inorganic semiconductor (for example, silicon) is immersed in a solution containing hydrofluoric acid and connected in an electrolytic cell configuration. This process is similar to that described in Pamulapati, et al. (U.S. Pat. No. 5,427,648), the disclosure of which being incorporated herein by reference. Anodic etching produces pores of a diameter of 1 through 100 nm.

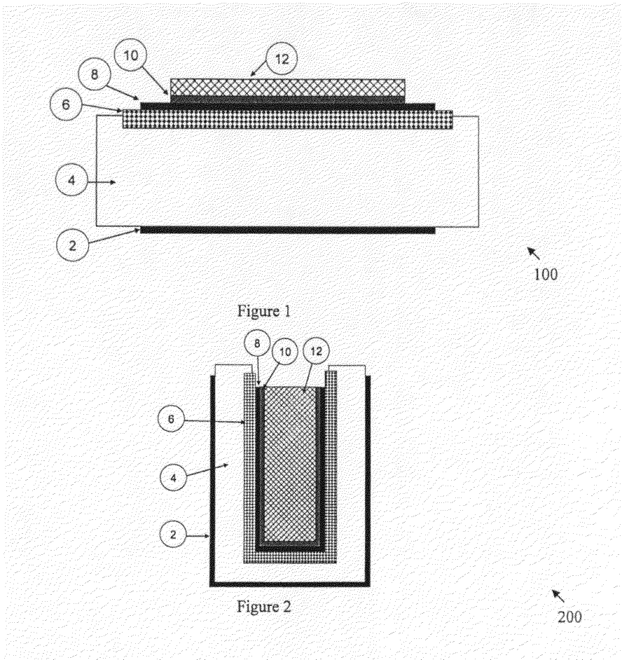

In accordance with the technical effects of the disclosed embodiments, the disclosed device is placed near a radioactive source in order to be proximate to the radiation emitted from that source. The radiation can take the form of electromagnetic radiation (i.e., photons), as well as condensed matter particles (e.g., alpha particles, beta particles, neutrons). In accordance with one particular implementation, the device can take a planar configuration, an example of which being illustrated in FIG. 1, in which the radioactive material 105 is deposited on one surface 110 of the device 100. However, it should be appreciated that the configuration of the device can be planar (as in FIG. 1), cylindrical (as illustrated in FIG. 2), a parallelepiped, or any other shape that is utility for various applications.

As shown in FIG. 1, the energy conversion device 100 includes a first electrode 2, porous silicon 4, quantum dots 6 dispersed in the porous silicon and a second electrode. The radioactive material 105 functions as an emitter radiation, e.g., particles alpha, beta, or gamma and x-rays.

In at least one embodiment of this disclosure, particles that transform one type of radiation into another may be present in the host matrix, in addition to the quantum dots, in order to sensitize the invention to specific types of radiation.

In accordance with at least one embodiment of this disclosure, one or more layers of intervening material may be placed between the energy conversion device and the radioactive source. This intervening material 5 is shown in both FIGS. 1 and 2. The intervening material(s) can be selected or configured to have one or more functions including serving as electrical insulation between the radioactive source and the energy conversion device. The intervening material(s) can be selected or configured to modify the properties of the particles reaching the active volume of the energy conversion device (e.g., reduce the energy of the particles, filter out particles of low energy, etc.). Additionally, the intervening material(s) can be selected or configured to cause the energy of the particles emitted from the radioactive source to be transferred into other particles (e.g., x-rays or gamma-rays) incident on the device.

Disclosed embodiments may also provide an improvement upon earlier pre-nuclear battery devices (for example, U.S. Pat. No. 2,847,585), because such conventional devices have low effective cross-sections for capturing energy from high energy particles. Because the presently disclosed energy conversion devices can be implemented to use porous silicon as a host matrix for quantum dot composite material, the active volume in which radioactive particles deposit energy that can be transformed into electricity can be made with a large thickness.

Additionally, the use of quantum dot materials of high atomic number increases the stopping power of the radioactive particles and their likelihood of interacting with the active volume of the disclosed embodiment devices. Accordingly, the cross-section of the active volume of the energy conversion devices of the disclosed embodiments can be much greater than in conventionally known devices. This larger cross-section enables the use of a much wider range of radioisotopes and the capture of a greater amount of energy derived from the radioisotope, resulting in greater power output for devices of comparable size. Therefore, the larger efficiency of conversion possible in the current invention enables the use of nuclear batteries in a wider range of applications.

Additionally, the use of additive materials dispersed in the host matrix may improve the sensitivity, or expand the selection of types of radiation sensed, in the disclosed embodiment devices. For example, the use of additive materials containing hydrogen, helium, lithium, or boron, may enable the sensing of, or the extraction of electrical power from, neutron radiation. The additive materials can take the form of dispersed molecules or particles. The particles may range in size between 1 nm and 100 μm.

We claim:

1. An assembly for converting radiation to electricity, comprising:
a host matrix of inorganic semiconducting material defining a first surface and a second surface and a thickness disposed between the first and second surfaces;
a plurality of nanoparticles interspersed within the thickness of the host matrix, the plurality of nanoparticles in combination with the host matrix generating at least one charge carrier upon interaction with the radiation;
a first electrode disposed adjacent to the first surface of the host matrix; and
a second electrode disposed adjacent to the second surface of the host matrix,
wherein, the generated electricity is output from the pair of the first and second electrodes.

2. The assembly of claim 1, wherein the radiation converted to electricity is at least one of the following: infrared, visible light, ultraviolet light , x-rays, gamma rays, beta rays, cosmic rays, and geothermal radiation.

3. The assembly of claim 1, wherein the thickness between the first and second surfaces is in the range of 0.01 micrometers and 10 centimeters.

4. The assembly of claim 1, wherein at least a portion of host matrix is of porous silicon.

5. The assembly of claim 1, further comprising a source of radiation provided in proximity to the host matrix so as to provide irradiation of the host matrix.

6. The assembly of claim 1, further comprising at least one layer of intervening material provided in between the source of radiation and the host matrix.

7. The assembly of claim 1, wherein materials dispersed within the matrix enhance conversion of radiation to electricity or enable the device to convert specific types of radiation to electricity.

8. An assembly for converting radiation to electricity, comprising:
a host matrix defining a first surface and a second surface and a thickness disposed between the first and second surfaces;
a plurality of nanoparticles interspersed within the thickness of the host matrix, the plurality of nanoparticles in combination with the host matrix generating at least one charge carrier upon interaction with the radiation;
a first electrode disposed adjacent to the first surface of the host matrix; and
a second electrode disposed adjacent to the second surface of the host matrix,
wherein, the generated electricity is output from the pair of the first and second electrodes, and
wherein the plurality of nanoparticles enables charge transport from particle to particle in at least one particle network within the host matrix.

9. The assembly of claim 8, wherein the radiation converted to electricity is at least one of the following: infrared, visible light, ultraviolet light, x-rays, gamma rays, beta rays, cosmic rays, neutrons, and geothermal radiation.

10. The assembly of claim 8, wherein the thickness between the first and second surfaces is in the range of 0.01 micrometers and 10 centimeters.

11. The assembly of claim 8, wherein at least a portion of host matrix is of porous silicon.

12. The assembly of claim 8, further comprising a source of radiation provided in proximity to the host matrix so as to provide irradiation of the combination of quantum dots and host matrix.

13. The assembly of claim 8, further comprising at least one layer of intervening material provided in between the source of radiation and the host matrix.

14. The assembly of claim 8, wherein materials dispersed in the host matrix interact with radiation to aid in the conversion of radiation to electricity.
